(19) United States
(12) Patent Application Publication
(10) Pub. No.: US 2019/0234576 A1
(43) Pub. Date: Aug. 1, 2019

(54) Optical System

(71) Applicant: Varroc Lighting Systems, s.r.o., Senov u Noveho Jicina (CZ)

(72) Inventors: Tomas Mateju, Bartosovice (CZ); Tomas Gloss, Vitkov (CZ)

(21) Appl. No.: 16/262,339

(22) Filed: Jan. 30, 2019

(30) Foreign Application Priority Data
Jan. 31, 2018 (CZ) PV 2018-53

(51) Int. Cl. F21S 41/365; F21S 43/40; F21S 41/20; F21S 43/20; H05K 1/18

(52) U.S. Cl. CPC F21S 41/365; F21S 43/40; F21Y 2115/10; F21S 43/255; H05K 1/18; F21S 41/20

(57) ABSTRACT

The invention relates to an optical system comprising two rows of light sources (1a, 1b) formed by LEDs. In each case, the entire row of light sources (1a, 1b) is arranged on one side of a double-sided printed circuit board (2) and each source (1a, 1b) in each row is associated with its own reflector (3a, 3b), whereby in front of the two rows of reflectors (3a, 3b) is arranged one optical filter (4), which is common to the two rows of reflectors (3a, 3b) and on whose output surface are provided pads (5) which are divided into two groups (51, 52), whereby each group (51, 52) is adapted to refract the light beams (6a, 6b) from the respective row of light sources (1a, 1b) to the direction (x) of illumination after these beams (6a, 6b) have been reflected from the respective row of reflectors (3a, 3b) associated with the respective row of the light sources (1a, 1b) and after these reflected beams (6a, 6b) have passed through the filter (4).

### TECHNICAL FIELD

The invention relates to an optical system comprising two rows of light sources formed by LEDs.

### BACKGROUND ART

In motor vehicle lighting, two functions of one lighting device are often required behind one output surface of a light image generated from the beams of a light source by reflection from the surface of a reflector using a filter and an optical element. However, the drawback is above all different light homogeneity and efficiency of both functions.

An optical system of this type comprises at least two light sources mounted on a printed circuit board/boards, a reflector with a cup-shaped inner surface for the reflection of the light source beams, a filter with optical elements which serves to pass the output light beams from the light device to create a light image on an imaging surface.

DE10140692 discloses a solution with two light sources and one reflector and a filter, wherein one light source is at the focal point of the reflector and this light is collimated by the reflector, while the second light source illuminates the material of the reflector itself, the light propagates through reflections in the reflector and is led out from the face of the reflector in a similar direction to the direction of the light coming from the first source, whereby the filter serves to scatter the incident light from the reflector. The disadvantage of this solution is different efficiency and different homogeneity of the light emitted for each function in the given optical system.

CZ305372 describes a solution in which a single LED is located on opposite sides of a common board. The LED is associated with a single reflector, whereby they are arranged behind a common lens with two focal points and each of the two reflectors is tilted to a given focal point. In addition, a shield is assigned to one reflector. Thus, the document describes an optical solution which uses a common bifocal lens, and this solution can be used only for the function of a main headlamp with a dimmed light function.

Document EP2012056B1 describes a solution of an optical system where a single-sided printed circuit board is used where the respective pair of LEDs (each LED belonging to one function) belong to a pair of Fresnel lenses (pairs of catadioptres) which have wedges on the output surface to refract light to the required direction. The light is then refracted through two filters and scattered in the x-axis direction and around the x-axis, whereby the first filter refracts the light, the second filter scatters the light. Both lenses, including the two filters, are made as one element belonging to the respective pair of LEDs. For a longer design shape, a plurality of these optical elements must be used.

It is the object of the invention to provide an optical system, especially for a lighting device, which solves the inclination of the reflectors behind a filter with optical elements, while maintaining the maximum possible efficiency and homogeneous appearance of the light for each function in a given optical system. The invention is particularly intended for a function by which daily light/directional signaling or end/directional signaling is achieved.

### PRINCIPLE OF THE INVENTION

The aim of the invention is achieved by an optical system comprising two rows of light sources, whose principle consists in that in each case, the entire row of light sources is arranged on one side of a double-sided printed circuit board and each source in each row is associated with its own reflector, one optical filter being arranged in front of the two rows of reflectors, whereby the optical filter is common to both rows of reflectors and on the output surface of the optical filter are formed pads which are divided into two groups, each of these groups being adapted to refract light beams from the respective row of the light sources to the direction of illumination after these beams have been reflected from the respective row of reflectors associated with the respective row of the light sources and after the reflected beams have passed through the filter. Given that each row of the light sources serves one function, and the conditions for the path of the beams from the two rows are identical, the maximum possible efficiency is achieved for both functions.

It is advantageous if the surfaces of the pads of one/the first group are parallel to the beams passing through the filter from the upper row of the sources and the row of reflectors associated with them, while the surfaces of the pads of the second group are parallel to the beams passing through the filter from the lower row of the sources and the associated reflectors, whereby the beams from the upper row of the light sources, after passing the filter, are refracted on the pads of the second group, whereas the beams from the lower row of the light sources, after passing through the filter, are refracted on the pads of the first group. Thus, the same light homogeneity for both functions is achieved.

To improve the light homogeneity, it is advantageous if the pads have a side smaller than 1 mm.

In addition, it is advantageous if the pads of the individual groups are arranged in a checkerboard pattern.

For some functions, it is advantageous if at least one group of pads is formed with a predetermined level of light scattering. If both groups are formed in this manner, the level of light scattering of the first group can be different from that of the second group.

### DESCRIPTION OF DRAWINGS

The invention is schematically illustrated in the enclosed drawings, wherein

FIG. 1 shows a three dimensional view of an exemplary embodiment of the optical system,

FIG. 2 shows a side view of an exemplary embodiment of the optical system,

FIG. 3 is a cross-sectional view of an exemplary embodiment of the optical system, showing the light beams,

FIG. 4 is a three dimensional view of an exemplary embodiment of the optical system with a detailed illustration of the pads,

FIG. 5 is a detailed view of a cross-section of a filter showing the passage of the light beams and

FIG. 6 is a detailed view of the lay-out of the pads on the filter.

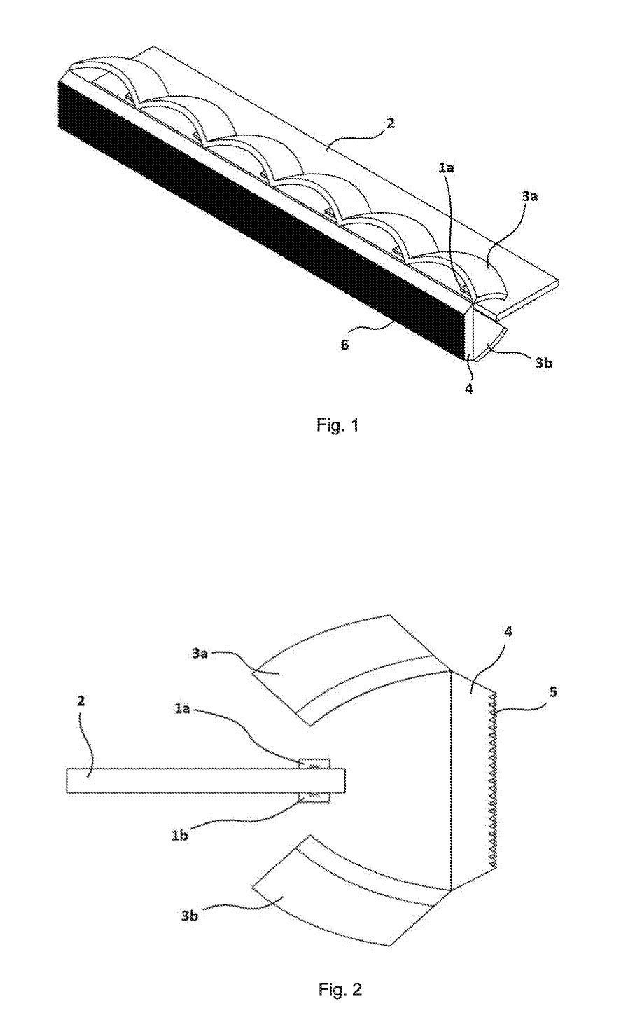

### EXAMPLES OF EMBODIMENT

The optical system according to the invention comprises a double-sided printed circuit board 2, on which light sources 1a, 1b are arranged in two rows. The light sources 1a, 1b consist of light-emitting diodes LEDs, each row of the light sources 1a, 1b being arranged on one side of the double-sided printed circuit board 2. Under the term “row” we understand the arrangement of light sources 1a, 1b side by side in a straight line or in a curve, according to the requirements for the construction of the optical system. To simplify the description, the rows of light sources 1a, 1b will be hereinafter referred to as the upper row of light sources 1a and the lower row of light sources 1b as shown in the drawings. However, using the invention, it can be seen that the double-sided printed circuit board 2 can be arranged in any direction which is selected for a given function on a specific vehicle, for example, vertically or obliquely. The rows of light sources 1a, 1b will be arranged in the same manner as the double-sided printed circuit board 2.

Each light source 1a, 1b in the row is associated with a reflector 3a, 3b. Consequently, on both sides of the printed circuit board, the reflectors constitute 2 rows which correspond to the light sources 1a, 1b. In front of the two rows of reflectors 3a, 3b, in the direction of light radiation, is arranged an optical filter 4, which is common to the two rows of reflectors 3a, 3b and on the outer front side is provided with pads 5.

From a side view of the optical system, it is evident that the reflectors 3a, 3b are tilted in the desired direction.

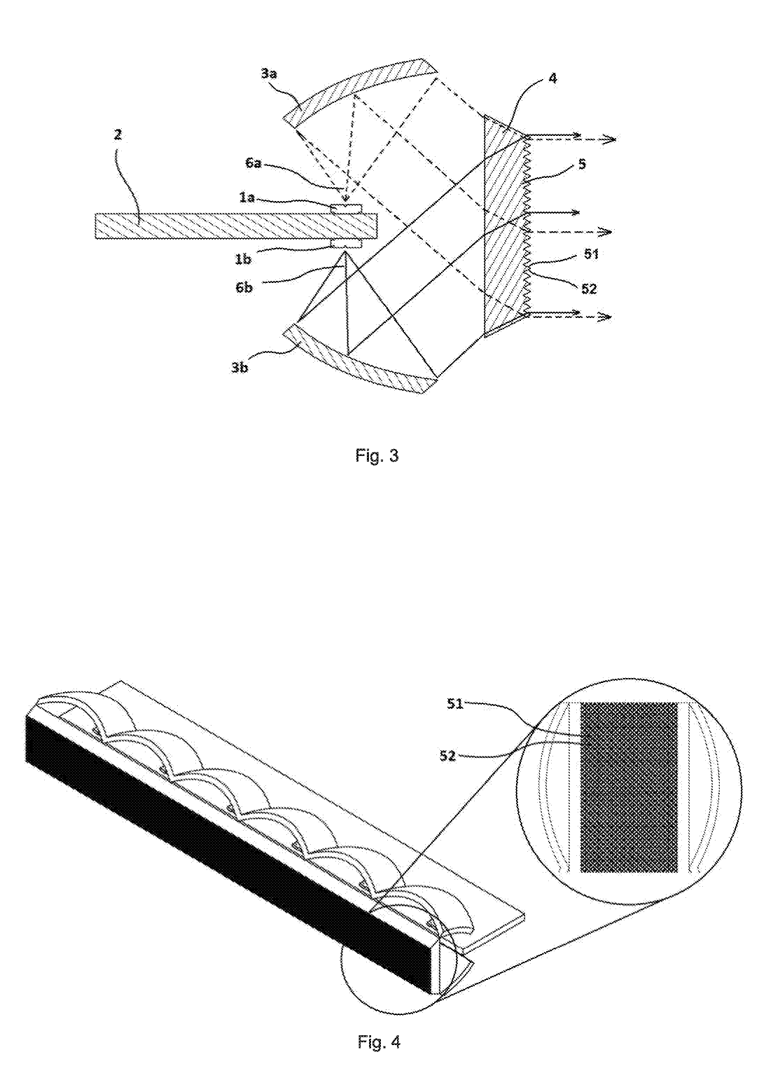

The optical principle of the optical system according to the invention is illustrated in FIG. 3 in an axial cross-section of the optical system. The beams 6a from the source 1a are directed towards the reflector 3a from which they are reflected and form a collimated bundle of beams 6a which fall on the filter 4 on whose surface they are refracted and pass through the filter 4 in a direction corresponding to the inclination of the first group of pads 51 to which these beams 6a are parallel and pass through the pads 5 of the second group 52 on which they are refracted and by which they are led out. The beams 6b from the source 1b are directed to the reflector 3b, from which they are reflected and form a collimated bundle of beams 6b, which fall on the filter 4, on which they are refracted and pass through the filter 4 in the direction corresponding to the inclination of the pads 5 of the second group 52, to which these beams 6b are parallel, and pass through the pads 5 of the first group 51, on which they are refracted and by which they are led out.

Thus, the first group 51 of pads 5 serve to lead out the beams 6b from the light sources 1b of the lower row, collimated by the reflector 3b, whereby these beams 6b are parallel to the second group 52 of pads 5, which is so-called invisible to these beams 6b. The second group 52 of pads 5 serves to lead out the beams 6a from the lights 1a of the upper row, collimated by the reflector 3a these beams 6a being parallel to the first group 51 of pads 5 which is invisible to them.

In FIG. 4, the two groups 51, 52 of pads 5 are shown in detail. One group, for example, the first group 51, is shown in white and the second group 52 in black, whereby the two groups 51, 52 are mutually laid-out in a checkerboard pattern. When the light sources 1a light up for the first function, for example, the light sources 1a of the upper row, the second group 52 of pads, shown in black, lights up. When the light sources 1b light up for the second function, for example, the light sources 1b of the lower row, the first group 51 of pads 5, shown in white, lights up. If the pads 5 are sufficiently small, in a preferred embodiment less than 1 mm, upon the lighting of each group 51, 52, a merging effect of the light beams occurs at a certain distance, whereby the pads of the unlit group visually disappear and, consequently, the light has a homogeneous appearance.

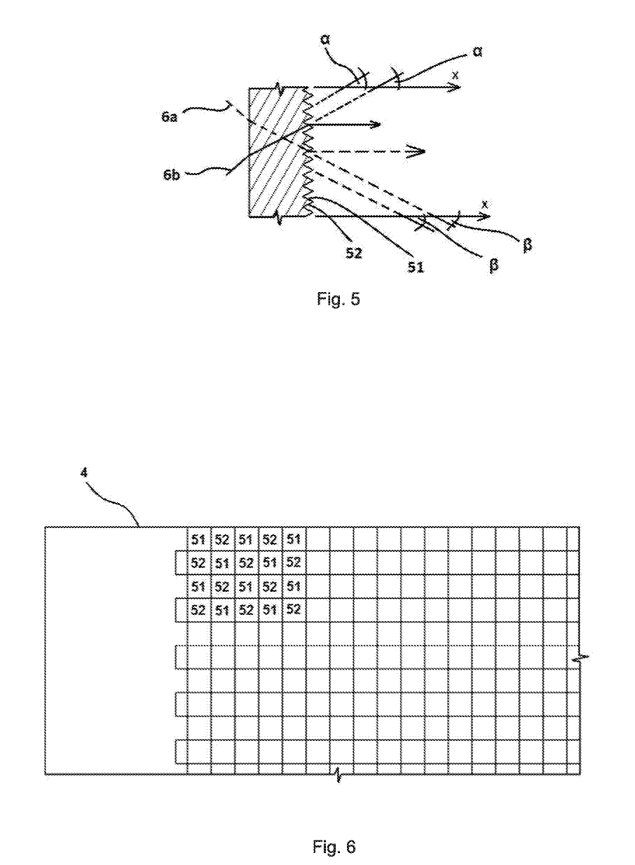

A detailed view of the arrangement of the pads 5 is shown in FIG. 5 in a vertical cross-section of the column of the pads 5 on the filter 4. The line interleaved with the refraction surface of the pads 5 of the second group 52 forms with the axis of illumination, which is identical to the direction x of illumination, an angle α, the same as the angle α of the beams 6b passing through the filter 4 from the source 1b and falling on the first group 51 of pads 5. The line interleaved with the surface of the pad from the first group 51 forms with the direction x of illumination an angle α, which is the same as the angle β of the beams 6a passing through the filter 4 from the source 1a and falling on the second group 52 of the pads 5. In the embodiment shown, the angles α and β are the same, but they can also be different.

FIG. 6 shows a detailed view of the checkerboard lay-out of the pads 5 on the filter 4, where the sides of the pads from the first group 51 adjoin the sides of the pads from the second group 52 and, at the same time, the apexes of the pads of the first group 51 adjoin diagonally the apexes of the pads of the first group 51 whereby the sides of the pads of the second group 52 adjoin the side of the pads of the first group 51 and, at the same time, the apexes of the pads from the second group 52 adjoin diagonally the apexes of the pads from the second group 52.

In an unillustrated embodiment, at least one group 51 or 52 of pads is formed with a predetermined level of light scattering. If both groups 51, 52, are formed with a predetermined level of light scattering, the level of light scattering of the pads of both groups 51, 52 can be the same, or the level of light scattering of the first group 51 is different from that of the second group 52.

### INDUSTRIAL APPLICABILITY

The invention is intended especially for headlights and rear lights of motor vehicles.

### LIST OF REFERENCES

1a light sources of the upper row
1b light sources of the lower row
2 double-sided printed circuit board
3a reflectors of the upper row
3b reflectors of the lower row
4 filter
5 pad
51 first group of pads
52 second group of pads
6a beams from the light sources of the upper row
6b beams from the light sources of the lower row

1. The optical system comprising two rows of sources (1a, 1b) formed by LEDs, characterized in that in each case the entire row of the light sources (1a, 1b) is arranged on one side of a double-sided printed circuit board (2) and each source (1a, 1b) in each row is associated with its own reflector (3a, 3b), whereby in front of the two rows of reflectors (3a, 3b) is arranged one filter (4), which is common to the two rows of reflectors (3a, 3b) and on the output surface of which are formed pads (5) which are divided into two groups (51, 52), whereby each group (51, 52) is adapted to refract light beams (6a, 6b) from the respective row of light sources (1a, 1b) to the direction (x) of illumination after these beams (6a, 6b) have been reflected from the respective row of reflectors (3a, 3b) associated with the respective row of the light sources (1a, 1b) and after these reflected beams (6a, 6b) have passed through the filter (4).

2-7. (canceled)
